(19) United States
(12) Patent Application Publication
(10) Pub. No.: US 2014/0154859 A1
(43) Pub. Date: Jun. 5, 2014

(54) Methods and Vehicles for High Productivity Combinatorial Testing of Materials for Resistive Random Access Memory Cells

(71) Applicant: INTERMOLECULAR INC., San Jose, CA (US)

(72) Inventors: Vidyut Gopal, Sunnyvale, CA (US); Tony P. Chiang, Campbell, CA (US); Imran Hashim, Saratoga, CA (US); Randall J. Higuchi, San Jose, CA (US); Robert A. Huertas, Hollister, CA (US); Hieu Pham, Santa Clara, CA (US); Yun Wang, San Jose, CA (US)

(73) Assignee: INTERMOLECULAR INC., San Jose, CA (US)

(21) Appl. No.: 13/705,516

(22) Filed: Dec. 5, 2012

(51) Int. Cl. H01L 49/02

(52) U.S. Cl. CPC H01L 28/20
USPC 438/382

(57) ABSTRACT

Provided are methods for processing different materials on the same substrate for high throughput screening of multiple ReRAM materials. A substrate may be divided into multiple site isolated regions, each region including one or more base structures operable as bottom electrodes of ReRAM cells. Different test samples may be formed over these base structures in a combinatorial manner. Specifically, each site isolated region may receive a test sample that has a different characteristic than at least one other sample provided in another region. The test samples may have different compositions and/or thicknesses or be deposited using different techniques. These different samples are then etched in the same operation to form portions of the samples. Each portion is substantially larger than the corresponding base structure and fully covers this base structure to protect the interface between the base structure and the portion during etching.

### BACKGROUND

A resistive random access memory (ReRAM) cells typically includes two electrodes and a resistive switching layer provided between these electrodes. The resistive switching layer may be formed from a metal oxide that displays multi-stable resistance characteristics such as transition metal oxides. A great number of materials have been considered for electrodes. Some of these electrode materials are capable of exchanging oxygen with resistive switching layers, while other may be relatively inert with respect adjacent layers. Furthermore, some ReRAM cells include various coupling layers. These layers serve as current limiters and/or current steering elements. Different ReRAM cells may be fabricated by varying composition, geometry, and/or processing of one or more components.

At this time, specific mechanisms governing ReRAM cell operation are still not well understood. Furthermore, predictive modeling capabilities, similar to Technology Computer Aided Design (TCAD) used for conventional metal oxide semiconductor field effect transistor (MOSFET) based memory cells, do not exist for ReRAM technology. As a result, ReRAM cells fabricated from different components need to be thoroughly tested to understand these mechanisms and develop predictive robust models and cell designs. A large number of possible variations call for high throughput, inexpensive, yet reliable methods for screening ReRAM materials.

### SUMMARY

Provided are methods for processing different materials on the same substrate for high throughput screening of multiple ReRAM materials. A substrate may be divided into multiple site isolated regions, each region including one or more base structures operable as bottom electrodes of ReRAM cells. Different test samples may be formed over these base structures in a combinatorial manner. Specifically, each site isolated region may receive a test sample that has a different characteristic than at least one other sample provided in another region. The test samples may have different compositions and/or thicknesses or be deposited using different techniques. These different samples are then etched in the same operation to form portions of the samples. Each portion is substantially larger than the corresponding base structure and fully covers this base structure to protect the interface between the base structure and the test sample during etching.

In some embodiments, a method involves providing a substrate that has a plurality of site isolated regions such that each site isolated region includes at least one base structure and forming test samples over the base structures in each of the site isolated regions. The test samples are formed in a combinatorial manner such that each site isolated region receives one test sample having a different characteristic than at least one test sample of another site isolated region. The method then proceed with etching the test samples in the same operation, wherein etching forms test sample portions from the test sample, each test sample portion fully covering a base structure provided under this test sample portion. In some embodiments, each test sample portion has a dimension, in the plane of the substrate, which is at least four times greater than a corresponding dimension of the base structure provided under this test sample portion. Each test sample portion may be concentric to the base structure provided under the test sample portion. This concentric feature applies to round and non-round profiled of the base structures and test sample portions. The concentric feature means that the centers of the two areas are aligned.

In some embodiments, each test sample portion has a dimension, in the plane of the substrate, which is at least 1 micrometer. Each base structure may have a dimension, in the plane of the substrate, which is less than 600 nanometers. Edges of each test sample portion and edges of the base structure that are provided under this test sample portion are separated by at least about 20 micrometers. In some embodiments, the base structures of the plurality of site isolated regions are formed from the same layer. At least one base structure of one site isolated region has a different composition than at least one base structure of another site isolated region. The substrate is cleaved into a plurality of dies prior to etching the test samples.

The method may involve forming one or more layers over the test samples such that the one or more layers and the test samples are etched in the same operation. Each layer portion formed during etching coincides with a test sample portion provided under this layer portion. At least one of these layer portions formed during etching forms a contact surface for making an electrical connection with a probe. The base structures may be operable as first electrodes of resistive switching memory cells. In some embodiments, the test sample portions are operable as resistive switching layers of the resistive switching memory cell. The layer portions are operable as second electrodes of the resistive switching memory cells.

In some embodiments, each base structure is electrically connected to a connector structure. The one or more of the connector structures are covered with one of the test samples prior to etching and are not covered by that test sample after etching. The test samples may be formed using one of a High Productivity Combinatorial Atomic Layer Deposition (HPC-ALD) technique or a High Productivity Combinatorial Physical Vapor Deposition (HPC-PVD) technique. In some embodiments, etching all of the test samples is performed using the same process conditions.

Provided is a method that involves providing a substrate having a first site isolated region and a second site isolated region. The first site isolated region includes a first base structure, while the second site isolated region includes a second base structure. The first base structure and the second base structure have the same composition and thickness. The method also involves forming a first test sample over the first base structure and forming a second test sample over the second base structure. The first test sample and the second test sample have different compositions. The method involves forming a layer over the first test sample and the second test sample and etching the first test sample, the second test sample, and the layer in the same operation. This etching forms a first stack comprising a portion of the first test sample and a first portion of the layer. The etching also forms a second stack including a portion of the second test sample and a second portion of the layer. The first stack fully covers the first base structure forming a first resistive random access memory cell and the second stack fully covers the second base structure forming a second resistive random access memory cell. Etching the first test sample, the second test sample, and the layer may be performed using the same process conditions.

These and other embodiments are described further below with reference to the figures.

### BRIEF DESCRIPTION OF THE DRAWINGS

FIG. 1 illustrates a schematic diagram for implementing combinatorial processing and evaluation using primary, secondary, and tertiary screening, in accordance with some embodiments.

FIG. 2 is a simplified schematic diagram illustrating a methodology for combinatorial process sequence integration that includes site isolated processing and/or conventional processing, in accordance with some embodiments.

FIG. 3 illustrates a schematic diagram of a substrate that has been processed in a combinatorial manner, in accordance with some embodiments.

FIG. 4 illustrates a schematic diagram of a combinatorial wet processing system, in accordance with some embodiments.

FIG. 5 illustrates a simplified schematic diagram illustrating a sputter chamber configured to perform combinatorial processing, in accordance with some embodiments.

FIGS. 6A-6B illustrate examples of ALD or CVD showerheads used for combinatorial processing, in accordance with some embodiments.

FIGS. 7A and 7B illustrate schematic representations of a ReRAM cell in a high resistive state (HRS) and low resistive state (LRS), in accordance with some embodiments.

FIG. 7C illustrates a plot of a current through a ReRAM cell as a function of a voltage applied to the ReRAM cell, in accordance with some embodiments.

FIG. 8A illustrates a schematic representation of a substrate having eight site isolated regions, in accordance with some embodiments.

FIG. 8B illustrates a schematic representation of a site isolated regions having twelve dies, in accordance with some embodiments.

FIG. 8C illustrates a schematic representation of a dies having three test chips, each test chip including four test sites, in accordance with some embodiments.

FIG. 8D illustrates a schematic top view a test site illustrating various components of a test vehicle provided on the test site, in accordance with some embodiments.

FIG. 8E illustrates a schematic cross-sectional representation of a test vehicle, in accordance with some embodiments.

FIG. 8F illustrates a schematic cross-sectional representation of a test vehicle, in accordance with some embodiments.

FIG. 9 illustrates a process flowchart corresponding to a method of testing materials, in accordance with some embodiments.

FIG. 10A-10D illustrates a schematic representation of a test vehicle during various stages of testing, in accordance with some embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

High Productivity Combinatorial™ (HPC™) (High Productivity Combinatorial™ and HPC™ are trademarks of Intermolecular, Inc.) processing is a promising approach that allows testing different samples on the same semiconductor substrate. This approach increases testing throughput and likelihood of finding optimum materials for various applications, such as Resistive Random Access Memory (ReRAM). HPC methodology involves parallel processing of multiple site isolated regions provided on a substrate. Each site isolated region may be used for testing different materials and/or processing conditions. For example, a ReRAM cell may include two electrodes and a resistive switching layer provided between the two electrodes. In a typical production process, each one of these components is formed from a separate blanket layer that initially covers the entire substrate. As such, multiple ReRAM cells fabricated on the same substrate have the same composition, thickness, and are processed using the same conditions. The HPC approach allows varying one or more of these characteristics of one or more components among different site isolated regions provided in the same substrate. For example, test samples used to form resistive switching layers in ReRAM cells may have different compositions in different site isolated regions. As such, ReRAM cells will differ throughout the substrate.

Different test samples may be formed on the same substrate using HPC tools, such as Atomic Layer Deposition (ALD) apparatus or Physical Vapor Deposition (PVD) apparatus that have HPC capabilities. These apparatuses are capable of individually processing each site isolated region, e.g., by varying processing conditions and/or depositing different materials from one region to another region. For example, an HPC-PVD apparatus may be equipped with multiple sputtering guns and may be able to change processing gases, RF power, DC power, bias, and other conditions, mask portions of the substrate and provide other functions further described below. An HPC-ALD apparatus may deliver different processing gases to different regions and prevent cross-mixing.

One challenge that appears with processing different materials on the same substrate is simultaneous etching of these materials. A conventional process involves etching only one type of material and etching conditions may be optimized for this material, e.g., to ensure adequate etching of this material and to prevent damage of other surrounding structures. For example, an interface between a reactive electrode and resistive switching layer in a ReRAM cell generally needs to be protected. Without being restricted to any particular theory, it is believed that this interface is at least partially responsible for resistive switching characteristics of the ReRAM cell. However, conventional etching optimization is not suitable in an HPC approach because of material differences. Processing each site isolated region individually may be too cumbersome and defeats the goal of high throughput screening.

Provided methods and test vehicles are specifically designed to protect various areas of test vehicles during etching multiple site isolation regions. Materials provided in these site isolated regions may vary from one region to another in accordance with HPC approaches. Specifically, an interface between two layers may be protected by separately etching each of the layers and setting a larger boundary for the later etched layers. The smaller sized layer and the interface are protected by keeping the etching boundary away from the etch zone. As such, more aggressive etching conditions may be used for the later etched layer without a risk of damaging the interface. There is no need to tune etching conditions and layers having different characteristics may be etched using the same conditions.

Etching one layer in a stack prior to another layer and having differently sized layers may be also used for controlling of the interface area. The smaller bottom layer (i.e., the layer etched first) defines the interface and its size controls the interface area. Any number of layers provided over the bottom layer may be etched at the same time. Since all such layers will have a larger boundary than the bottom layer, little control of etching is needed.

The overall testing procedure may involve providing a substrate having multiple site isolation regions. Each site isolated region includes at least one base structure. In some embodiments, multiple base structures are provided in each site isolated region. Each base structure may be connected to a connector structure by, for example, a connector line provided within the substrate. A pair of the base and connector structures defines a test vehicle. Each site isolated region may include multiple test vehicles. The base structure may receive one or more other layers for testing materials in these layers, while the connector structure may be used to form a direct electrical connection to, for example, electrical leads. The base and connector structures may be formed during the same etching operation from the same layer. As such, these structures may have the same composition and thickness. However, the size of these structures with the substrate plane may be substantially different. The size of the base structure may be controlled to represent the actual interface in a ReRAM cell for example. On the other hand, the size of the connector structure may be large enough to make a direct electrical connection to its top surface with the test probe.

The testing may proceed with forming test samples over the base structures in a combinatorial manner. The combinatorial manner means that each site isolated region receives a test sample that has a different characteristic than at least one other test sample formed in another site isolated region. The differentiating characteristic may be composition, morphology, thickness, and the like. For example, test samples may have different compositions in different site isolated regions. These test samples may be deposited using various HPC deposition techniques, such as HPC-ALD or HPC-PVD. One test sample may initially cover multiple base structures and connector structures. Each test sample is then patterned to remove portions of it from the connector structures and retain a separate portion over each base structure.

Before patterning the test samples, the samples may be covered with one or more layers of other materials. In some embodiments, a layer having a uniform composition may cover all test samples provided in the substrate. Alternatively, some test samples may receive a layer having one composition, while other test samples may receive a layer having a different composition.

At this stage of testing (i.e., after forming test samples and all layers over the test samples), the substrate may be cleaved into multiple pieces for individual processing. Each piece may represent a different site isolated region. In some embodiments, cleaving is performed prior to etching. However, cleaving may be performed at a letter time, i.e., after etching.

In some embodiments, the substrate is further processed without cleaving the substrate. In other words, multiple different test samples are patterned while still being provided on the same substrate. This operation may involve etching the test samples and any layers provided over the test samples in the same operation. The etching conditions may be selected in such a way that all test samples are adequately etched despite their compositional and/or other differences.

These methods and test vehicles may be used for testing materials for ReRAM cells. A test vehicle for ReRAM testing may include a bottom electrode with an associated on-chip resistor. The bottom electrode may be formed into a base structure, while the on-chip resistor may be embedded into the base structure or formed into the connector line. Some examples of materials suitable for bottom electrodes include n-doped poly silicon, titanium nitride, platinum, ruthenium, and tungsten nitride. This test vehicle may be fabricated by depositing a layer of a suitable electrode material on a substrate. The substrate may include connector lines for connecting the later formed base structures to connector structures. As stated above, the connector structures are typically formed from the same layer as the base structures. The layer may be lithographically patterned to form the bottom electrodes having specific dimensions in the plane of substrate. These dimensions will later define the interface area between the bottom electrode and switching layer. The top surface of the bottom electrode is treated after patterning to reduce contamination.

The substrate may then be cleaved into multiple test coupons or kept intact as the original substrate. If the substrate is not cleaved, then each site isolated region may be processed separately. Overall, variability is introduced to different test coupons or site isolated regions by forming different test samples. These test samples may include resistive switching layers, top electrodes, and/or other components. The variability may be attributed to differences in composition, morphology, structure, processing conditions, and/or other characteristics.

### High Productivity Combinatorial (HPC) Examples

“Combinatorial Processing” generally refers to techniques of differentially processing multiple regions of one or more substrates. Combinatorial processing generally varies materials, unit processes or process sequences across multiple regions on a substrate. The varied materials, unit processes, or process sequences can be evaluated (e.g., characterized) to determine whether further evaluation of certain process sequences is warranted or whether a particular solution is suitable for production or high volume manufacturing.

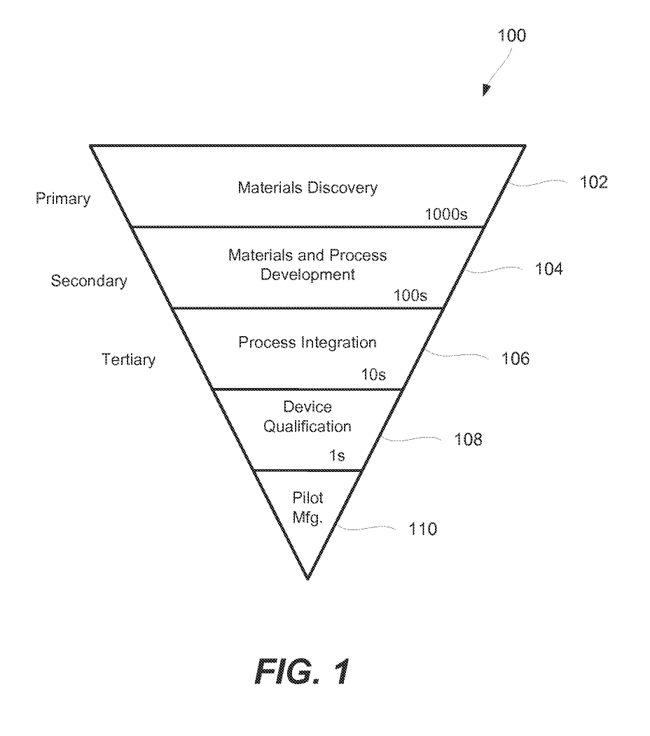

FIG. 1 illustrates a schematic diagram for implementing combinatorial processing and evaluation using primary, secondary, and tertiary screening, in accordance with some embodiments. Specifically, diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (i.e., microscopes).

Materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106, where tens of materials and/or processes and combinations are evaluated. Tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

Diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways. Additional aspects of High Productivity Combinatorial (HPC) techniques are described in U.S. patent application Ser. No. 11/674,137, filed on Feb. 12, 2007, which is hereby incorporated by reference in its entirety for purposed of describing HPC techniques.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate. For example, such structures may include, but would not be limited to, ReRAM cell components, such as electrodes, resistive switching layers, coupling layers, and the like. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

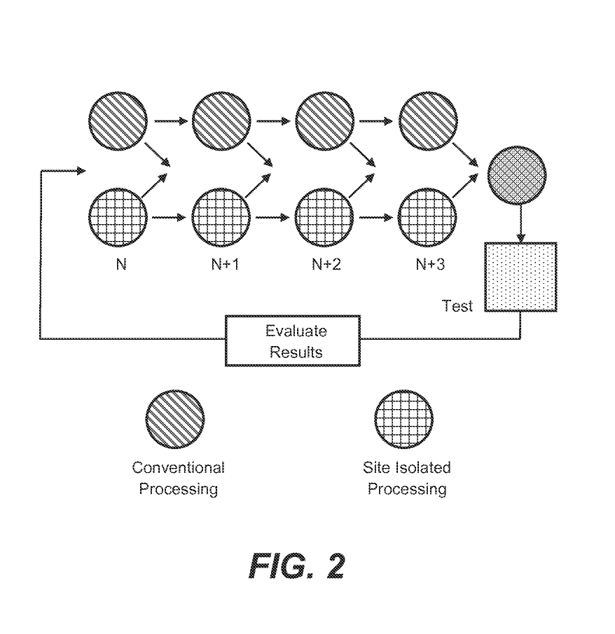

FIG. 2 is a simplified schematic diagram illustrating a general methodology for combinatorial process sequence integration that includes site isolated processing and/or conventional processing, in accordance to some embodiments. In some embodiments, the substrate is initially processed using conventional process N. In some embodiments, the substrate is then processed using site isolated process N+1. During site isolated processing, an HPC module may be used, some examples of which are described below. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Combinatorial processing can be used to produce and evaluate different materials, chemicals, processes, process and integration sequences, and techniques related to semiconductor fabrication. For example, combinatorial processing can be used to determine optimal processing parameters (e.g., power, time, reactant flow rates, temperature, etc.) of dry processing techniques such as dry etching (e.g., plasma etching, flux-based etching, reactive ion etching (RIE)) and dry deposition techniques (e.g., physical vapor deposition (PVD), chemical vapor deposition (CVD), atomic layer deposition (ALD), etc.). Combinatorial processing can be used to determine optimal processing parameters (e.g., time, concentration, temperature, stirring rate, etc.) of wet processing techniques such as wet etching, wet cleaning, rinsing, and wet deposition techniques (e.g., electroplating, electroless deposition, chemical bath deposition, etc.).

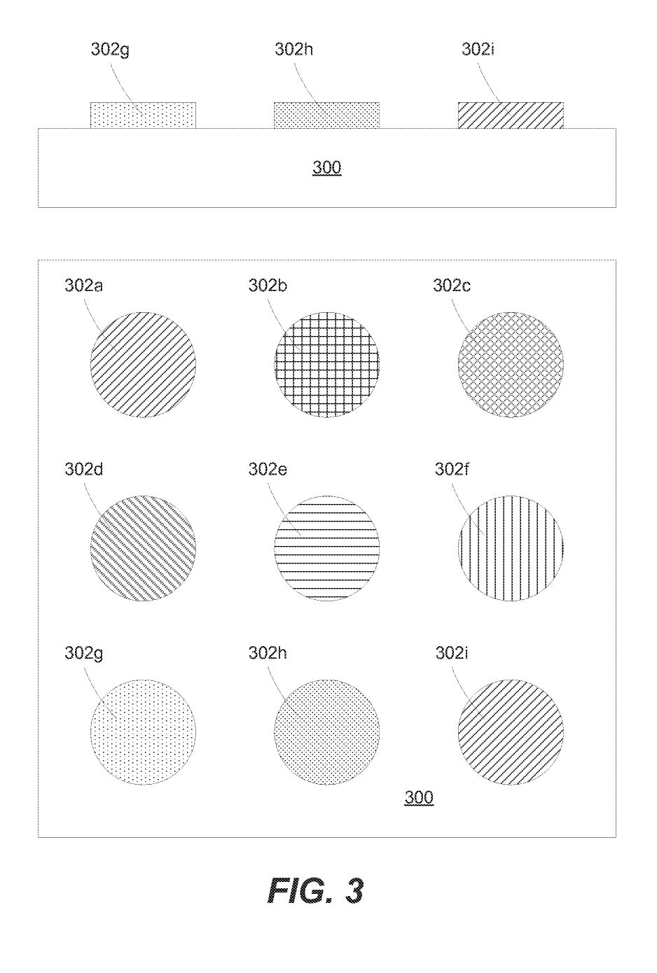

FIG. 3 illustrates a schematic diagram of a substrate 300 processed in a combinatorial manner, in accordance with some embodiments. Substrate 300 is shown to have nine site isolated regions 302a-302i. Although substrate 300 is illustrated as being a generally square shape, those skilled in the art will understand that the substrate may be any useful shape such as round, rectangular, etc. The lower portion of FIG. 3 illustrates a top down view while the upper portion of FIG. 3 illustrates a cross-sectional view taken through the three site isolated regions 302g-302i. The shading of the nine site isolated regions illustrates that the process parameters used to process these regions have been varied in a combinatorial manner. The substrate may then be processed through a next step that may be conventional or may also be a combinatorial step as discussed earlier with respect to FIG. 2.

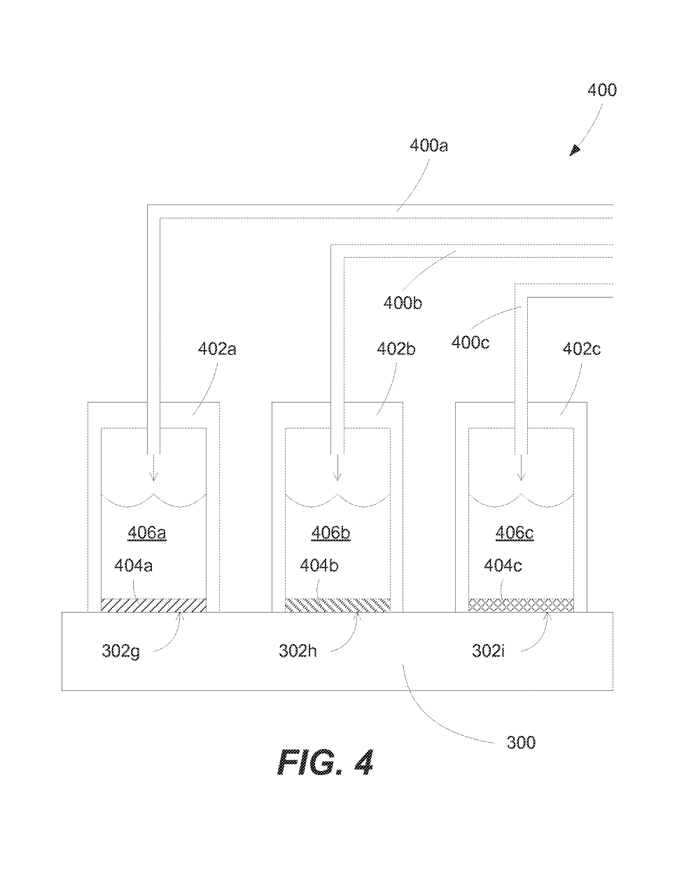

FIG. 4 illustrates a schematic diagram of a combinatorial wet processing system 400, in accordance with some embodiments. System 400 may be used to investigate materials deposited or, more generally, processed using solution-based techniques. Those skilled in the art will realize that this is only one possible configuration of a combinatorial wet system. FIG. 4 illustrates a cross-sectional view of substrate 300 taken through the three site isolated regions 302g-302i similar to the upper portion of FIG. 3 described above. Solution dispensing nozzles 400a-400c supply solutions 406a-406c having different compositions (i.e., different solution chemistries 406a-406c) to chemical processing cells 402a-402c. FIG. 4 illustrates the deposition of layers 404a-404c within respective site isolated regions 302g-302i. Although FIG. 4 illustrates a deposition step, other solution-based processes such as cleaning, etching, surface treatment, surface functionalization, and the like may be investigated in a combinatorial manner. The solution-based treatment can be customized for each of the site isolated regions.

In some embodiments, the dielectric layer is formed through a deposition process, such as chemical vapor deposition (CVD), atomic layer deposition (ALD), or physical vapor deposition (PVD). The metal electrode layer can be formed by PVD, CVD or ALD through a shadow mask or by a lithography patterning process.

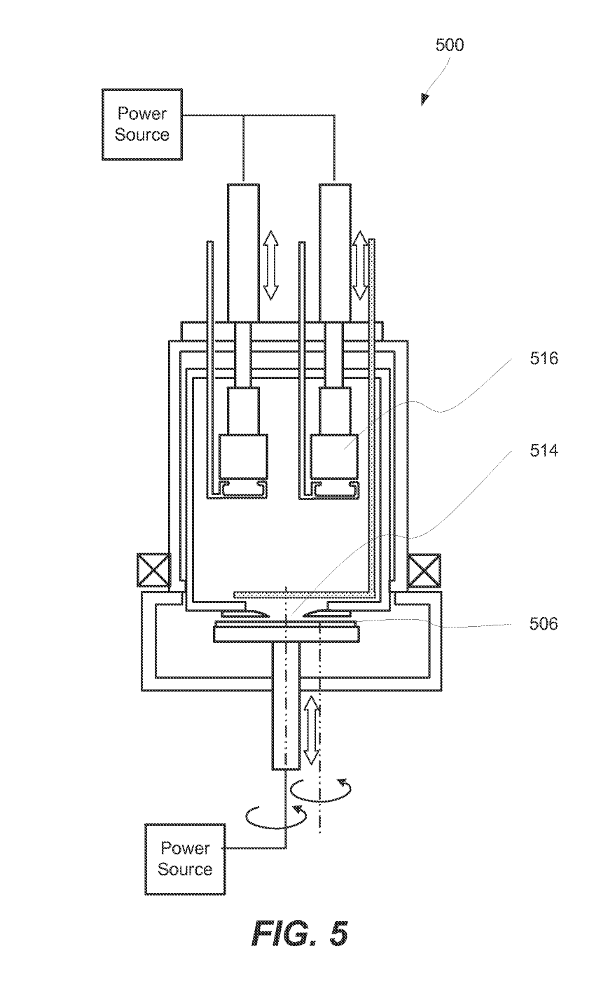

FIG. 5 illustrates a simplified schematic diagram illustrating a sputter system 500 configured to perform combinatorial processing, in accordance with some embodiments. Sputter system 500 generally includes a process chamber, one or more sputtering sources 516, and a transport system capable of positioning substrate 506, such that any area of the substrate can be exposed to sputtered material. Sputter system 500 can further include an aperture 514 positioned under sputtering sources 516. Aperture 514 is typically smaller than substrate 506 so that discrete regions of substrate 506 can be subjected to distinct process conditions in a combinatorial manner. However, there is no particular limit on the size of aperture 514. Typical apertures can range from a minimum of about 10 mm in one dimension, and can be square, round, or rectangular, for example. For combinatorial processing, the apertures are small enough such that materials can be deposited on a plurality of site-isolated regions on a substrate. For high deposition rate sputtering to coat an entire substrate, the aperture can be up to approximately full substrate size.

The chamber of sputter system 500 provides a controlled atmosphere so that sputtering can be performed at any gas pressure or gas composition necessary to perform the desired combinatorial processing. Typical processing gases include argon, oxygen, hydrogen, or nitrogen. However, additional gases can be used as desired for particular applications. The transport system includes a substrate support capable of controlling substrate temperature up to about 550° C., and applying a bias voltage of a few hundred volts.

Multiple sputtering sources 516 may be positioned at an angle so that they can be aimed through a single aperture 514 to a site-isolated region on substrate 506. The sputtering sources 516 may be positioned about 100-300 mm from the aperture 514 to ensure uniform flux to the substrate within the site-isolated region. Additional details of the combinatorial PVD system are described in U.S. patent application Ser. No. 12/027,980 filed on Feb. 7, 2008 and U.S. patent application Ser. No. 12/028,643 filed on Feb. 8, 2008, both of which are herein incorporated herein by reference for purposes of describing combinatorial PVD system.

In some embodiments, a deposition process can be performed in the sputter system 500 in a combinatorial manner. The combinatorial deposition process generally includes exposing a first site-isolated region of a surface of substrate 506 to material from one or more sputtering sources 516 under a first set of process parameters, and exposing a second site-isolated region of a surface of substrate 506 to material from the one or more sputtering sources 516 under a second set of process parameters. During exposure of the surface of the substrate to the sputtering source, the remaining area of the substrate is not exposed to the material from the sputtering target, enabling site-isolated deposition of sputtered material onto the substrate. The combinatorial process can further include exposing three or more site-isolated regions of the substrate to material from a sputtering source under distinct sets of process parameters. The combinatorial process can further include depositing additional layers onto any site-isolated region to build multi-layered structures if desired. In this manner, a plurality of process conditions to deposit one or a plurality of layers can be explored on a single substrate under distinct process parameters.

The process parameters that can be combinatorially varied generally include sputtering parameters, sputtering atmosphere parameters, substrate parameters, or combinations thereof. Sputtering parameters typically include exposure times, power, sputtering target material, target-to-substrate spacing, or a combination thereof. Sputtering atmosphere parameters typically include total pressure, carrier gas composition, carrier gas flow rate, reactive gas composition, reactive gas flow rate, or combinations thereof. The reactive gas flow rate can be set to greater than or equal to zero in order to vary the reactive gas composition in an inert carrier gas. The substrate parameters typically include substrate material, surface condition (e.g., roughness), substrate temperature, substrate bias, or combinations thereof.

Substrates can be a conventional round 200 mm, 300 mm, or any other larger or smaller substrate/wafer size. In other embodiments, substrates may be square, rectangular, or other shape. One skilled in the art will appreciate that substrate may be a blanket substrate, a coupon (e.g., partial wafer), or even a patterned substrate having predefined regions. In some embodiments, a substrate may have regions defined through the processing described herein.

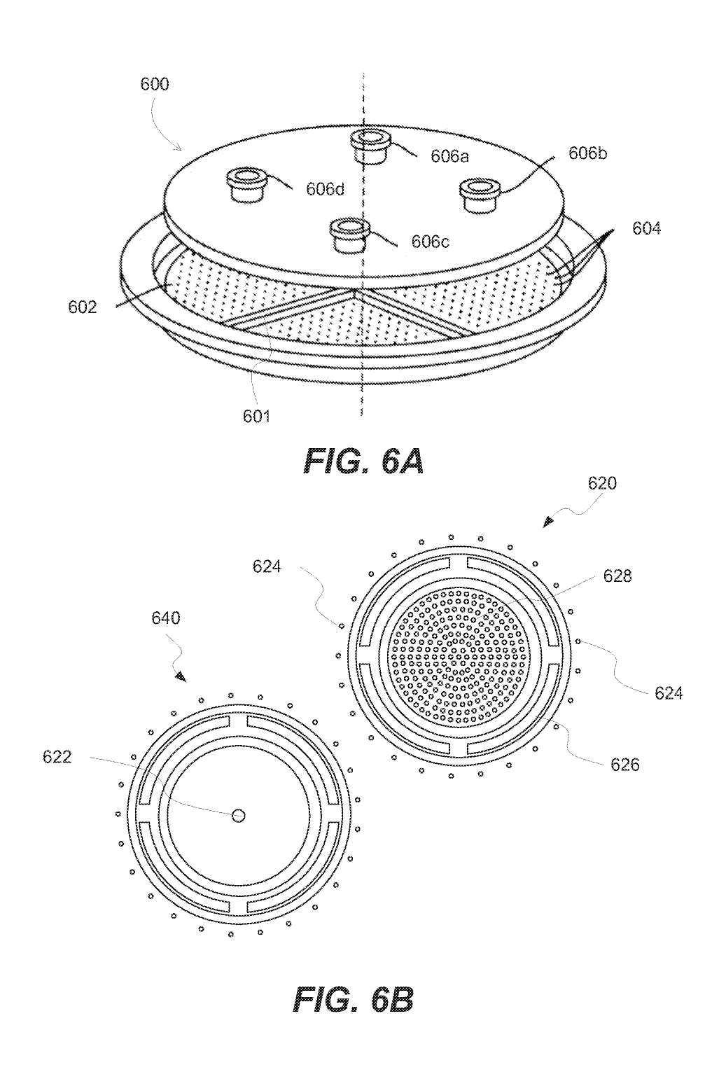

FIGS. 6A-6B illustrate examples of an ALD or CVD showerheads used for combinatorial processing, in accordance with some embodiments. Showerhead 600 illustrated in FIG. 6A includes four regions 602 used to deposit one or more materials on a substrate. As this example, up to four different materials and/or process conditions could be used to deposit materials in each of the four site isolated regions (e.g., quadrants in this example) of the same substrate (not shown). Processing gases, such as precursor gases, reactant gases, and purge gases, are introduced into each of four regions 602 of showerhead 600 through gas inlet conduits 606a-606b. Regions 602 are separated by dividers 601 to prevent cross-mixing of the processing gases within the showerhead. As such, different site isolated regions of the substrate receive different processing gases. Furthermore, showerhead 600 may be generate gas “skirts” along dividers 601 that prevent intermixing of the processing gases once they leave showerhead 600. For simplicity, each region is shown to have a single gas inlet conduit. Those skilled in the art will understand that each region of showerhead 600 may have multiple gas inlet conduits, e.g., one for precursors and one for inert gases. The gases exit each region 602 of showerhead 600 through holes 604 in the bottom of showerhead 600. The gases then travel to the substrate surface and react at the surface to deposit a material, etch an existing material on the surface, clean contaminants found on the surface, react with the surface to modify the surface in some way, etc. The showerhead illustrated in FIG. 6A may be used for CVD, plasma enhanced CVD (PECVD), ALD, or plasma enhanced ALD (PEALD).

FIG. 6B illustrates a bottom view of two showerheads 620 and 640, in accordance with some embodiments. Unlike the segmented showerhead described above with reference to FIG. 6A, showerheads 620 and 640 are used to supply only one mixture of the gases to the substrate. However, the size of showerheads 620 and 640 conform to the site isolated region. As such showerheads 620 and 640 are generally much smaller than the segmented showerhead described above with reference to FIG. 6A used to process multiple site isolated regions. Showerheads 620 and 640 are specifically designed to avoid the processes gas from traveling beyond site isolated regions during processing or, more specifically, after exhausting the processing gas from the showerhead. This gas control is achieved by a combination of the purge holes 624 and the exhaust channels 626 to ensure that each region under each showerhead can be processed in a site isolated manner.

Showerhead 640 includes a single gas distribution port 622 provided in the center of showerhead 640 for delivering reactive gases to the surface of the substrate. The small size of this showerhead (i.e., the size corresponding to the site isolated region) and specific process conditions and materials used ensure the uniformity despite using the single gas distribution port. If more control over uniformity is needed, showerhead with a plurality of gas distribution ports 628 for delivering process gases to the surface of the substrate may be used. This configuration can be used to improve the uniformity of the process on the substrate if required.

Showerheads 620 and 640 include a plurality of purge holes 624. These holes introduce inert purge gases (i.e. Ar, N2, etc.) around the periphery of each of showerheads 620 and 640 to insure that the regions under each showerhead can be processed in a site isolated manner. The gases, both the reactive gases and the purge gases, are exhausted from the process chamber through exhaust channels 626 that surround each of the showerheads. As stated above, the combination of the purge holes 624 and the exhaust channels, 626, ensure that each region under each showerhead can be processed in a site isolated manner. The diameter of the small spot showerhead (i.e. the diameter of the purge ring) can vary between about 40 mm and about 100 mm. Advantageously, the diameter of the small spot showerhead is about 65 mm.

### ReRAM Examples

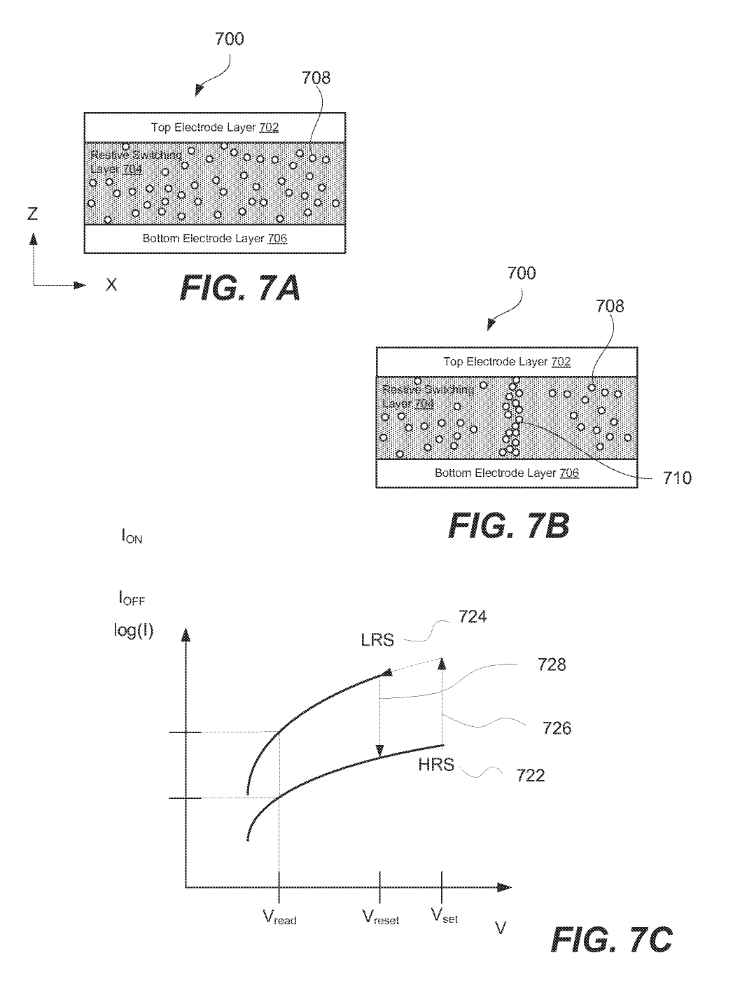

A brief description of ReRAM cells is presented below to provide better understanding of tested materials and methods and some unique testing consideration. A basic building unit of a ReRAM cell is a stack having a capacitor like structure. The ReRAM cell includes two electrodes and a dielectric material positioned in between these two electrodes. FIG. 7A illustrates a schematic representation of ReRAM cell 700 including top electrode 702, bottom electrode 706, and resistive switching layer 704 provided in between top electrode 702 and bottom electrode 706. It should be noted that the “top” and “bottom” references for electrodes 702 and 706 are used solely to differentiation the electrodes and not to imply any particular spatial orientation of the electrodes. In some examples, examples other references, such as “first” and “second” electrodes, are used instead. ReRAM cell 700 may also include other components such as an embedded resistor, diode, and other components.

As discussed above, resistive switching layer 704, which may be made of dielectric material, can be made to conduct through one or more filaments or conduction paths formed by applying a certain voltage. To provide this resistive switching functionality, resistive switching layer 704 includes a certain concentration of electrically active defects 708, which are sometimes referred to as traps. For example, some charge carriers may be absent from the structure (i.e., vacancies) and/or additional charge carriers may be present (i.e., interstitials) representing defects 708. In some embodiments, defects may be formed by impurities (i.e., substitutions). These defects may be utilized for ReRAM cells operating according to a valence change mechanism, which may occur in specific transition metal oxides and is triggered by a migration of anions, such as oxygen anions. Migrations of oxygen anions may be represented by the motion of the corresponding vacancies, i.e., oxygen vacancies. A subsequent change of the stoichiometry in the transition metal oxides leads to a redox reaction expressed by a valence change of the cation sublattice and a change in the electronic conductivity. In this example, the polarity of the pulse used to perform this change determines the direction of the change, i.e., reduction or oxidation. Other resistive switching mechanisms include bipolar electrochemical metallization mechanism and thermochemical mechanism, which leads to a change of the stoichiometry due to a current-induced increase of the temperature.

Without being restricted to any particular theory, it is believed that defects 708 can be reoriented within resistive switching layer 704 to form filaments or conduction paths as, for example, schematically shown in FIG. 7B as element 710. This reorientation of defects 708 occurs when a voltage for this type of resistive switching layer 704 is applied to electrodes 702 and 706. Sometimes, reorientation of defects 708 is referred to as filling the traps by applying a set voltage (and forming one or more filaments or conduction paths) and emptying the traps by applying a reset voltage (and breaking the previously formed filaments or conduction paths).

Defects 708 can be introduced into resistive switching layer 704 during or after its fabrication. For example, a certain concentration of oxygen deficiencies can be introduced into metal oxides during their deposition or during subsequent annealing. Physical vapor deposition (PVD) and atomic layer deposition (ALD) techniques may be specifically tuned to include particular defects 708 and their distribution within resistive switching layer 704. Doping and other techniques could be also used to create defects 708 in resistive switching layer 704.

Operation of ReRAM cell 700 will now be briefly described with reference to FIG. 7C illustrating a logarithmic plot of a current through a ReRAM cell as a function of a voltage applied to the electrode of ReRAM cell, in accordance with some embodiments. ReRAM cell 700 may be either in a low resistive state (LRS) defined by line 724 or high resistive state (HRS) defined by line 722. Each of these states is used to represent a different logic state, e.g., HRS representing logic one and LRS representing logic zero or vice versa. Therefore, each ReRAM cell may be used to store one bit of data. It should be noted that some ReRAM cells may have three and even more resistive states allowing multiple bit storage in the same stack. One having ordinary skills in the art would understand application of this example to more complex ReRAM cell architectures.

HRS and LRS are defined by presence or absence of one or more filaments or conduction paths in resistive switching layer 704. For example, a ReRAM cell may be initially fabricated in LRS and then switched to HRS. A ReRAM cell may be switched back and forth between LRS and HRS many times, defined by set and reset cycles. Furthermore, a ReRAM cell may maintain its LRS or HRS for a substantial period of time and withstand a number of read cycles.

The overall operation of ReRAM cell 700 may be divided into a read operation, set operation, and reset operation. During the read operation, the state of ReRAM cell 700 or, more specifically, the resistance of resistive switching layer 704 can be sensed by applying a sensing voltage, which is sometimes referred to as a “read” voltage and indicated as VREAD in FIG. 7C, to electrodes 702 and 706. If ReRAM cell 700 is in HRS represented by line 722, the external read and write circuitry connected to electrodes 702 and 706 will sense the resulting “off” current (I_{OFF}) that flows through ReRAM cell 700. As stated above, this read operation may be performed multiple times without switching ReRAM cell 700 between HRS and LRS. In the above example, the ReRAM cell 700 should continue to output the “off” current (I_{OFF}) when the read voltage (V_{READ}) is applied to the electrodes.

Continuing with the above example, when it is desired to switch ReRAM cell 700 into a different logic state, ReRAM cell 700 is switched from its HRS to LRS. This operation is referred to as a set operation. This may be accomplished by using the same read and write circuitry to apply a set voltage (V_{SET}) to electrodes 702 and 706. Applying the set voltage (V_{SET}) forms one or more filaments or conduction paths in resistive switching layer 704 and switches ReRAM cell 700 from its HRS to LRS as indicated by dashed line 726. In LRS, the resistance characteristics of ReRAM cell 700 are represented by line 724. In this LRS, when the read voltage (V_{READ}) is applied to electrodes 702 and 706, the external read and write circuitry will sense the resulting “ON” current (I_{ON}) that flows through ReRAM cell 700. Again, this read operation may be performed multiple times without toggling ReRAM cell 700 between HRS and LRS. Continuing with the above example and ReRAM cell 700 being in LRS, ReRAM cell 700 should continue to output the “OFF” current (I_{OFF}) when the read voltage (V_{READ}) is applied to the electrodes.

It may be desirable to switch ReRAM cell 700 into a different logic state again by switching ReRAM cell 700 from its LRS to HRS. This operation is referred to as a reset operation and should be distinguished from set operation during which ReRAM cell 700 is switched from its HRS to LRS. During the reset operation, a reset voltage (V_{RESET}) is applied to resistive switching layer 704 to break the previously formed filaments or conduction paths in resistive switching layer 704 and switches ReRAM cell 700 from its LRS to HRS as indicated by dashed line 728. Reading of ReRAM cell 700 in its HRS is described above. Overall, ReRAM cell 700 may be switched back and forth between its LRS and HRS many times. Read operations may be performed in each of these states (between the switching operations) one or more times or not performed at all.

ReRAM cell 700 may be configured to have either unipolar switching or bipolar switching. The unipolar switching does not depend on the polarity of the set voltage (V_{SET}) and reset voltage (V_{RESET}) applied to the electrodes 702 and 706 and, as a result, to resistive switching layer 704. In the bipolar switching the set voltage (V_{SET}) and reset voltage (V_{RESET}) applied to resistive switching layer 704 need to have different polarities.

In some embodiments, the write voltage (V_{WRITE}) is between about 100 mV and 10V or, more specifically, between about 500 mV and 5V. The length of write voltage pulses (t_{WRITE}) may be less than about 100 milliseconds or, more specifically, less than about 5 milliseconds and even less than about 100 nanoseconds. The read voltage (V_{READ}) may be between about 0.1 and 0.5 of the write voltage (V_{WRITE}). In some embodiments, the current during reading operations is greater than about 1 mA or, more specifically, is greater than about 5 mA to allow for a fast detection of the state by reasonably small sense amplifiers. The length of read voltage pulse (t_{READ}) may be comparable to the length of the corresponding write voltage pulse (t_{WRITE}) or may be shorter than the write voltage pulse (t_{WRITE}).

In some embodiments, a set voltage (V_{SET}) and resent voltage (V_{RESET}) dependent on the thickness of resistive switching layer 704. Without being restricted to any particular theory it is believed that this behavior is indicative of a bulk-mediated switching mechanism. Generally, the bulk-mediated switching mechanism forms percolation paths through the bulk of resistive switching layer 704. Materials exhibiting this behavior include higher bandgap metal oxides (i.e., oxides with a bandgap greater than 4 eV), such as hafnium oxide, aluminum oxide, tantalum oxide, zirconium oxide, and yttrium oxide. It should be noted that these oxides includes specifically formed defects and therefore are distinguishable from typical oxides of these metals, e.g., stoichiometric oxides containing no impurities. As such, it is possible to reduce required voltages by scaling down the thickness of resistive switching layer 704. Other materials, such as titanium oxide and niobium oxide, require substantially the same set and reset voltages over a wide span of their thicknesses.

### Substrate and Base Test Vehicle Examples

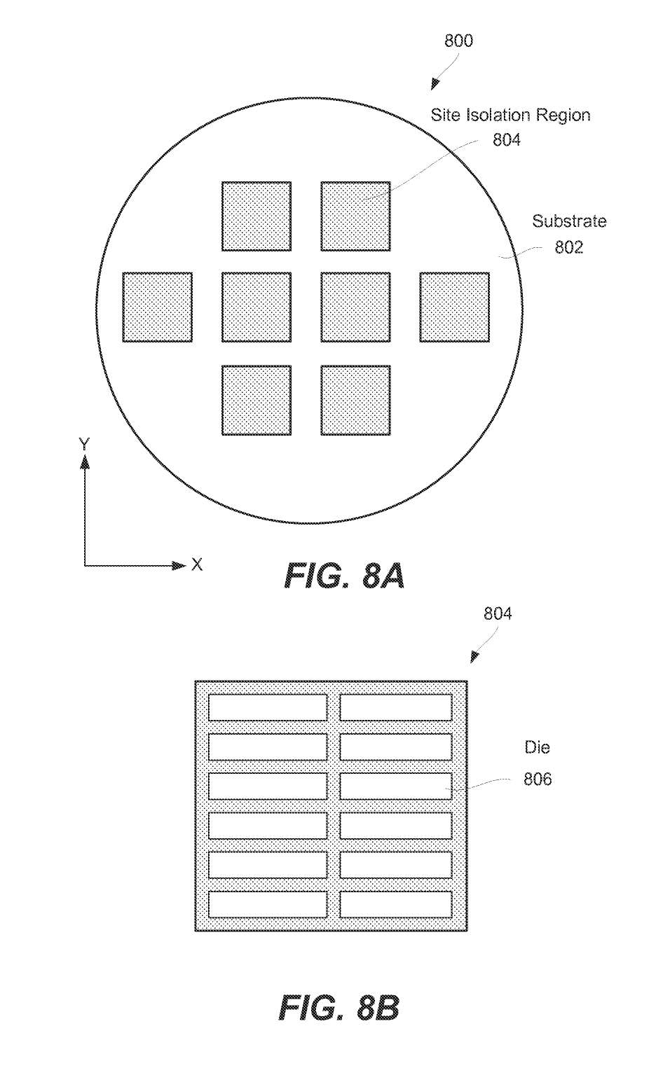

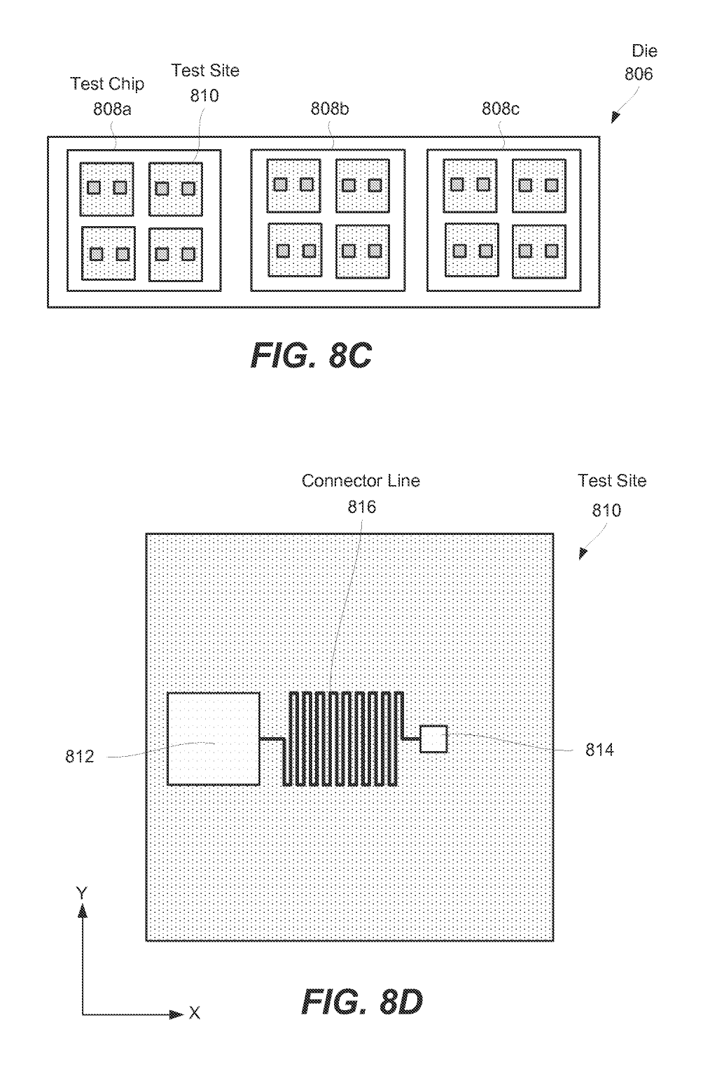

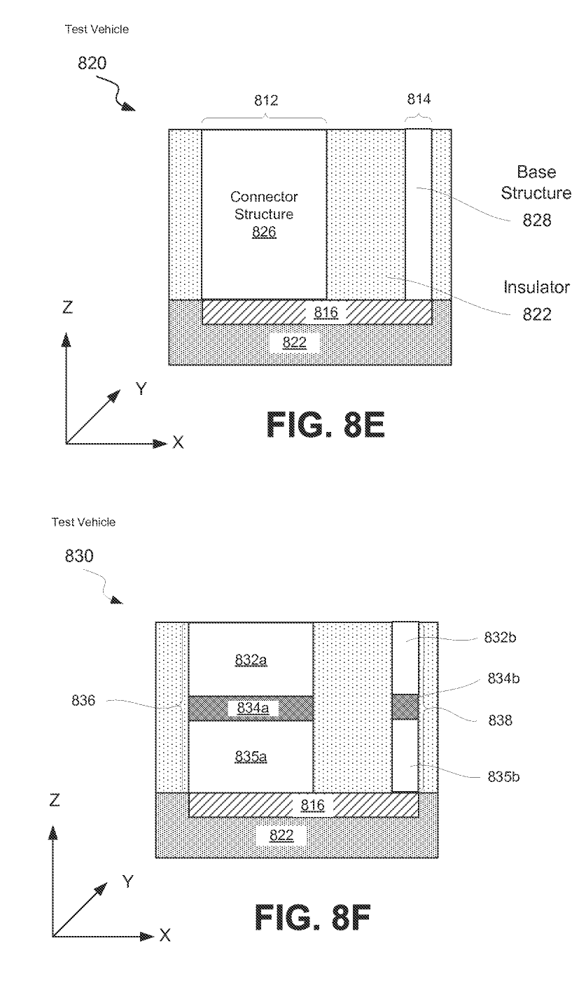

As stated above, a substrate may include multiple site isolated regions used for testing different materials and/or other parameters. The substrate may also include test vehicles for providing electrical connections to the tested materials, in particular, to the substrate facing sides of the tested materials. The test vehicles may also be used to create and control interfaces between selected components of the test vehicles and tested materials. For example, an area of the interface or combination of the materials forming the interface may be controlled by specific test vehicles. The test vehicles provided on the same substrate and, more specifically, within the same site isolated region may have different structures, resistances, and/or characteristics as described below with reference to FIGS. 8A-8F.

FIG. 8A illustrates a schematic representation of a substrate 802 having eight site isolated regions 804, in accordance with some embodiments. In general, any number of site isolated regions may be provided on the same substrate. Site isolated regions 804 may have a rectangular, square, round, or any other shape. Some examples of site isolated regions are described below with reference to the HPC methodology. Each one of site isolated regions 804 may include multiple dies 806 as shown in FIG. 8B. For example, a site isolated region may include twelve dies or any other number of dies. Each die 806 may include multiple test chips, e.g., three test chips 808a-808c, as shown in FIG. 8C.

Test vehicles included in these test chips 808a-808c may vary from one test chip to another. For example, the difference may be in a form of connector resistances. All test vehicles of test chip 808a may have the same resistance of their connector lines.

However, this resistance may be different from the resistance of connector lines used in test vehicles of test chip 808b or ones used in test vehicles of test chip 808c. Furthermore, the resistance of connector lines used in test vehicles of test chip 808c may be still different from ones used in chips 808a and 808b. In a specific example, the resistance of a connector provided on one test chip may be about 9 kOhm (e.g., 9+/−1 kOhm), the resistance of each connector provided on another test chip may be about 62 kOhm (e.g., 62+/−1 kOhm), and the resistance of each connector provided on yet another test chip may be about 816 kOhm (e.g., 816+/−1 kOhm). All these test chips may be a part of the same die. Other resistance values and configurations of test chips may be used as well.

Each test chip may include multiple test sites 810 as, for example, shown in FIG. 8C illustrating four test sites 810 provided in each test chip. Each test site may include one or more test vehicles. In some embodiments, test vehicles provided at different test sites may differ from each other in terms of the contact area formed by the base structure. As further described below, a test vehicle may include a base structure and connector structure protruding to the surface of the insulator materials and forming two contact surfaces. The bottom end of the base and connector structures are interconnected by a connector line. The base structure is configured to receive a test sample over its contact surface, while the contact surface of the connector structure may be used for making a direct electrical connection by a probe. As such, the size of the connector structure or, more specifically, its contact surface is generally kept the same and sufficiently large for a probe connection. The size of the base structure or, more specifically, the size of its contact surface may vary to test different sizes of interfaces between the base structures and tested materials. In some embodiments, the contact surfaces of the base structures may be about 130 nanometers in size in one test site, about 150 nanometers in size in another site, about 350 nanometers in size in yet another site, and about 500 nanometers in size for another site. These sizes may represent side lengths of square contact areas, in some embodiments. Other sizes, shapes, and configurations of contact surface may be used as well.

FIG. 8D illustrates a schematic top view of test site 810 including a test vehicle showing two contact surfaces 812 and 814, with contact surface 812 corresponding to the connector structure and contact surface 814 corresponding to the base structure. Generally, contact surface 812 corresponding to the connector structure has a smaller size than contact surface 814 corresponding to the base structure. The base structure and connector structure are interconnected by connector line 816. Connector line 816 may have a wavy (e.g., square wave) shape in order to increase its length and, as a result, its resistance. Connector line 816 makes electrical connections to bottom portions of each stack as shown in FIGS. 8E and 8F.

FIG. 8E illustrates a schematic cross-sectional side view of test vehicle 820, in accordance with some embodiments. Specifically, test vehicle 820 includes connector line 816 provided within a substrate and interconnecting bottoms of connector structure 826 and base structure 828. Connector line 816 is made from a conductive material. Some examples of suitable conductive materials include tungsten. In some embodiments, the distance between connector structure 826 and base structure 828 is between about 1 micrometer and 100 micrometers or, more specifically, between about 10 micrometers and 50 micrometers. This distance is measured between centers of connector structure 826 and base structure 828. Materials and geometry of connector line 816 are specifically selected to achieve a specific resistance of connector line 816. This resistance may be between about 5 kOhm and 182 kOhm, such as about 9 kOhm, about 62 kOhm, or about 116 kOhm. Other resistance values may be used as well. In some embodiments, connector line 816 is specifically shaped in the X-Y plane (as, e.g., illustrated in FIG. 1D) to achieve a desired resistance of connector line 816.

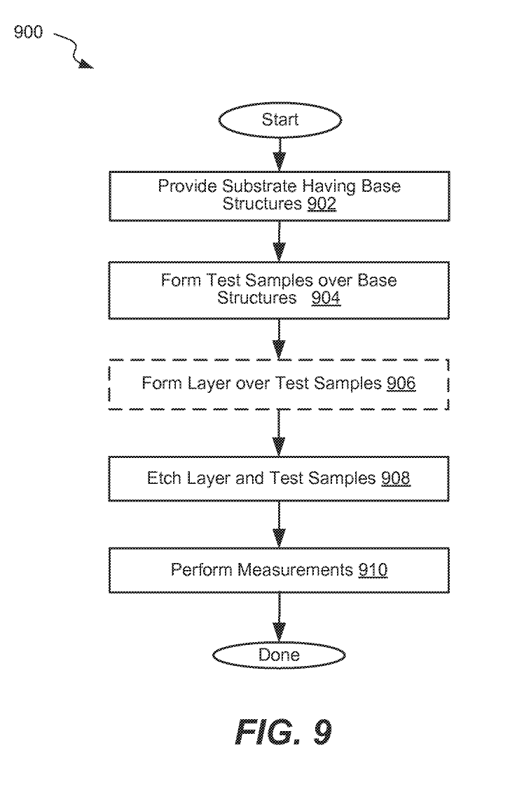

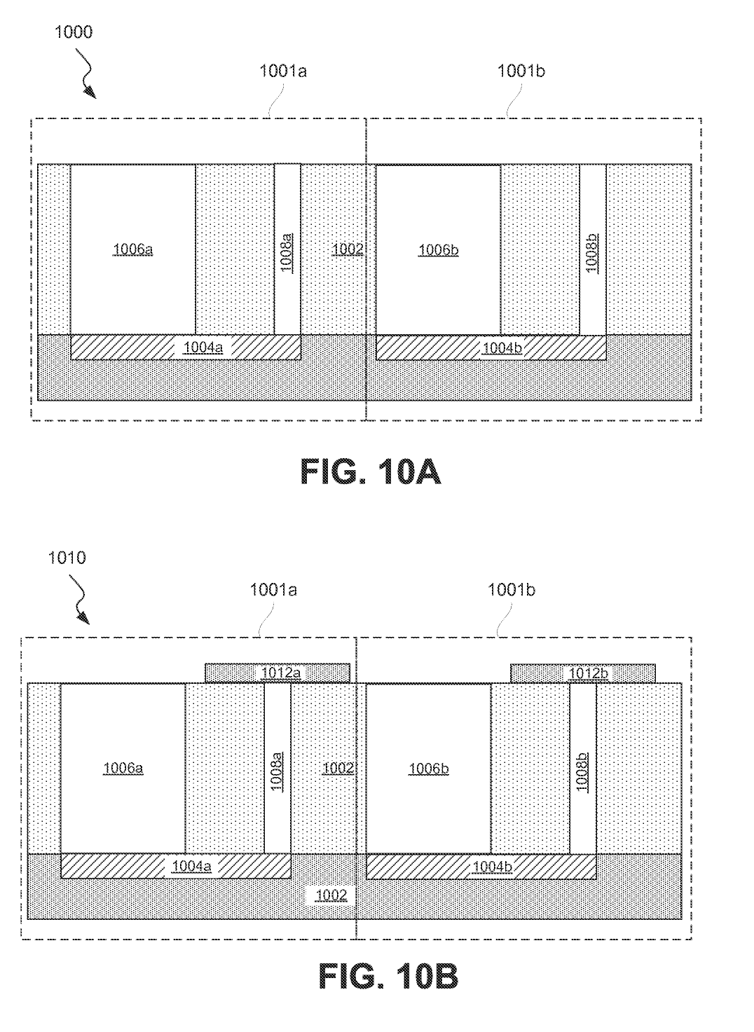

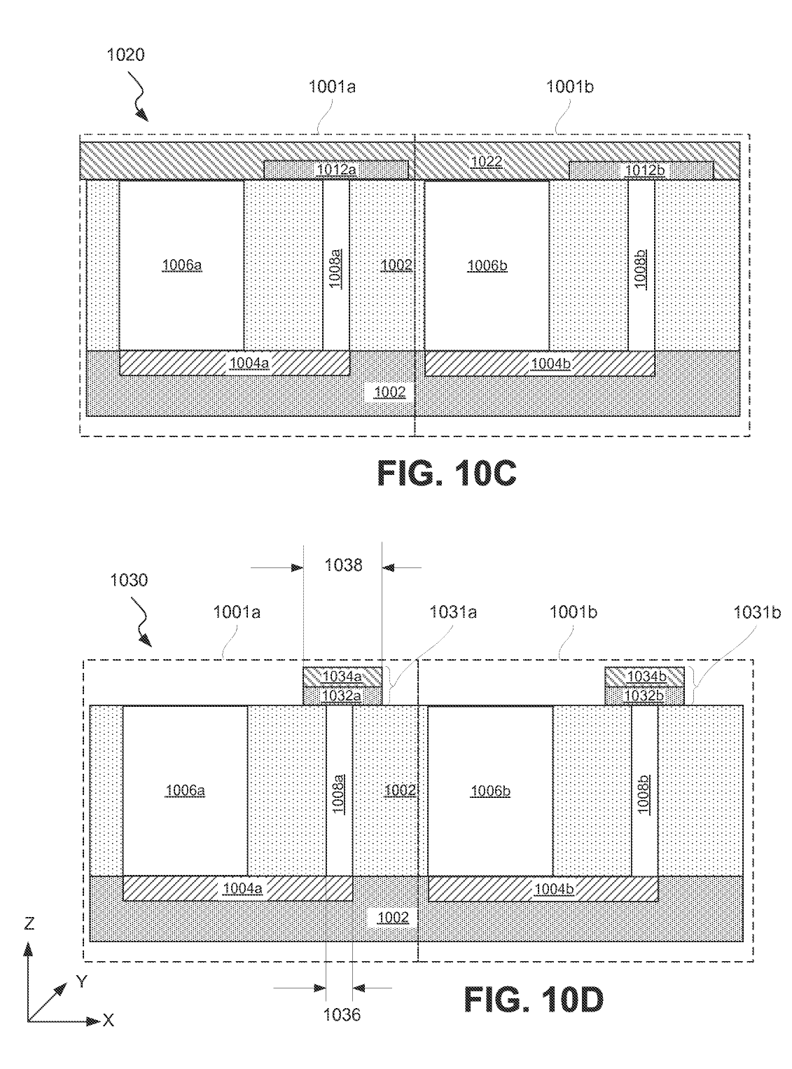

Connector structure 826 and base structure 828 extend through insulator 822 made from an insulating material. Some examples of suitable insulating materials for insulator 822 include silicon dioxide. The height of connector structure 826 and base structure 828 may be substantially the same as the thickness of insulator 822. In some embodiments, this thickness may be between about 0.1 micrometers and 5 micrometers or, more specifically, between 0.2 micrometers and 1 micrometer. As stated above, connector structure 826 includes contact surface 812, while base structure 828 includes contact surface 814. Contact surface 812 may be used for establishing a direct electrical connection to a probe. Contact surface 814 is used for depositing a test sample as further described below with reference to FIGS. 9 and 10A-10D. Contact surfaces 812 and 814 may coincide with the top surface of insulator 822.

Connector structure 826 and base structure 828 may have the same composition and height (extending in the Z direction) and, in sole embodiments, the same sets of layers as further explained below with reference to FIG. 8F. The composition and thickness similarities may result from both structures being formed from the same layer (or sets of layers as in FIG. 8F). For example, a layer containing an electrode material may be formed on the substrate and then patterned (e.g., etched) to form connector structure 826 and base structure 828. Electrode materials may include silicon (e.g., n-doped poly-silicon and p-doped poly-silicon), silicides, silicide-germanides, germanides, titanium, titanium nitride (TiN), platinum, iridium, iridium oxide, ruthenium, ruthenium oxide, and the like. In this example, base structure 828 may be operable as a bottom electrode and interface with a resistive switching layer (formed as a test sample).

However, connector structure 826 and base structure 828 may have different dimensions measured in the X-Y plane, i.e., the plane perpendicular to the height of connector structure 826 and base structure 828. In other words, dimensions of contact surfaces 812 and 814 may be different. Contact surface 812 may be at least about 1 millimeter in size, while contact surface 814 may be less than about 1 millimeter in size, e.g., between about 100 nanometers and 600 nanometers. Furthermore, sizes of contact surfaces 812 may vary from one test vehicle to another, such as about 130 nanometers for one vehicle, 150 nanometers for another, 350 nanometers for yet another one, or 500 nanometers for some other vehicles.

FIG. 8F illustrates a schematic representation of another test vehicle 830 in which connector structure 836 and base structure 838 each includes more than one layer. For example, base structure 838 may include an embedded resistor provided between two portions 832b and 835b of polysilicon. The material forming an embedded resistor may be also integrated as layer 834a of connector structure 836. The additional resistance caused by layer 834a needs to be accounted for during testing. However, the resistance of layer 834a may be substantially less than the resistance of layer 834b due to the difference in their dimensions in the substrate plane. Alternatively, an embedded resistor may be incorporated into a stack provided over base structure 838 as further explained above. In this example, the resistance of connector structure 836 is not affected.

In some embodiments, a current steering element (e.g., a diode) may be incorporated into a base structure. In this situation, the corresponding connector structure cannot include a similar current steering element, since such a combination of the two current steering elements will prevent current flow through the test vehicle in either direction. As such, the connector structure may be partially or completely removed from the test vehicle. In the case of complete removal of the connector structure, a probe may be connected directly to the connector line (element 816). Removal of a portion of the connector structure may leave some electrode material over the connector line and the probe may be connected to this residual material.

The current steering element can be a diode, or other suitable steering element that exhibits non-ohmic conduction by selectively limiting the voltage across and/or the current flow through the resistive switching layer. In some embodiments, the current steering element allows current to flow through the ReRAM cell in only one direction. Alternatively, a steering element, such as a punch-through diode, may allow the current to flow through the ReRAM cell in either direction. In some embodiments, a current steering element may conduct little or no current below some predetermined threshold voltage applied to the element. Appropriate biasing schemes may be used to differentiate a test vehicle or, more specifically, a ReRAM cell formed on the test vehicle. In some embodiments, a steering element is formed from a polycrystalline semiconductor material such as polysilicon, a polycrystalline silicon-germanium alloy, polygermanium or any other suitable material. For example, the steering element may include n-doped polysilicon region, undoped polysilicon region above the n-doped polysilicon region, and p-doped polysilicon region the undoped region.

### Processing Examples

FIG. 9 illustrates a process flowchart corresponding to a method 900 of testing materials and, more specifically, screening materials for ReRAM application, in accordance with some embodiments. Method 900 may commence with providing a substrate including multiple site isolated regions during operation 902. Each site isolated region may include at least one base structure. This base structure may be a part of a test vehicle and may be electrically connected to a corresponding connector structure of the same test vehicle. In some embodiments, a site isolated region includes multiple base structures to perform parallel experiments on a test sample formed in this site isolated region. Some base structures in the same site isolated region may have the same or similar characteristics. Some may vary based on the size of their contact surfaces. Various examples of base structures and corresponding test vehicles are described above with reference to FIGS. 8A-8C.

In some embodiments, all base structures formed on a substrate have the same composition. For example, all base structures may be formed from the same layer. Alternatively, base structures in one site isolated region may have different characteristics (e.g., have different composition) from base structures in other site isolated regions. This variability may be created by employing HPC techniques described above.

FIG. 10A illustrates a schematic representation of substrate 1000 that may be provided during operation 902 (described above with reference to FIG. 9), in accordance with some embodiments. Substrate 1000 includes two test vehicles 1001a and 1001b. Test vehicles 1001a and 1001b may be provided in the same or different site isolated regions. Each test vehicle includes a base structure, a connector structure, and a connector line interconnecting the base and connector structures. Specifically, test vehicle 1001a includes base structure 1008a, connector structure 1006a, and connector line 1004a, while test vehicle 1001b includes base structure 1008b, connector structure 1006a, and connector line 1004b.

Returning to FIG. 9, method 900 may proceed with forming multiple test samples during operation 904. The test samples may be formed over the base structures and each test sample may cover multiple base structures. This operation may be performed in a combinatorial manner, which means that each site isolated region may receive a different kind of a test sample. For example, a test sample formed in one site isolated region may have a different composition than a test sample formed in one other site isolated region or, more specifically, than a test sample in any other site isolated region. In some embodiments, test samples may vary based on their structural characteristics (e.g., thicknesses), morphology, and other characteristics. The test samples may be formed using HPC-PVD and/or HPC-ALD techniques described above. The HPC methodology allows varying characteristics of test samples from one site isolated region to another.

In some embodiments, test samples formed during operation 904 may include resistive switching materials. Specifically, these test samples may be later formed into resistive switching layers of the cells. Some examples of suitable materials include carbon polymers, perovskites, and certain metal oxides (MeOx) and metal nitrides (MeN) such as nickel oxide (NiO), niobium oxide (Nb₂O₅), titanium oxide (TiO₂), hafnium oxide (HfO₂) aluminum oxide (Al₂O₃), tantalum oxide (Ta₂O₅), zirconium oxide (ZrO₂), and yttrium oxide (Y₂O₃), scandium oxide (Sc₂O₃) magnesium oxide (MgOx), chromium dioxide (CrO₂), vanadium oxide (VO), boron nitride (BN), and aluminum nitride (AlN). The thickness of these test samples may be between about 10 Angstroms and 500 Angstroms or, more specifically, between about 50 Angstroms and 200 Angstroms.

FIG. 10B illustrates a schematic representation of substrate 1010 that may be formed during operation 904, in accordance with some embodiments. Test sample 1012a is formed over base structure 1008a, while test sample 1012b is formed over base structure 1008b. The test samples may extend over other components of the test vehicle, such as contact structures, at least prior to their etching. More specifically, a test sample may extend over most of the surface of the site isolated region (even covering the contact structures) but not into adjacent site isolated region. In this example, one test sample may cover multiple test vehicles including their base structure and contact structures. The test sample is then patterned to remove it from the contact structures. If test vehicles 1001a and 1001b are from different site isolated regions, then some characteristics of test samples 1012a and 1012b may vary. For example, test samples 1012a and 1012b may have different composition, morphology, and/or thickness.

Returning to FIG. 9, method 900 may proceed with operation 906 during which one or more layers are formed over the test samples. In a ReRAM example, the base structures may be operable as bottom electrodes, while the test samples may include resistive switching materials. Another layer may be formed over the test samples and include an electrode material. The test samples and layer are patterned to form resistive switching layers and top electrodes. In some embodiments, one or more of these layers are formed as embedded resistors and/or current steering elements provided in the stacks over the base structures. Operation 906 is optional and, in some embodiments, the test samples formed during operation 904 are etched in operation 908 without forming any layer over the test samples.

Each layer formed during operation 906 may have the same composition, thickness, and other characteristics in all site isolated regions of the substrate. For example, one or more blanket layers may be formed during this operation covering the entire surface of the substrate. In other embodiments, one or more layers may vary from one site isolated region to another. For example, different compositions of top electrodes may be tested in this manner.

FIG. 10C illustrates a schematic representation of substrate 1020 that may be formed during operation 906 described above, in accordance with some embodiments. Substrate 1020 includes layer 1022 formed over test samples 1012a and 1012b. Layer 1022 is shown to be a continuous layer. In some embodiments, the layer may be segmented. For example, different parts of the layer may be provided in different site isolated regions. Furthermore, the substrate may include multiple layers formed over the test samples after operation 906. Each one of these layers may be continuous or segmented.

Returning to FIG. 9, method 900 may proceed with etching multiple test samples in the same operation, i.e., operation 908. Any layer that may be present over the test samples at this point (i.e., formed during operation 906) may be also etched in the same operation together with the test samples. In this case, the etching forms stacks, each stack including a test sample portion and one or more layer portions. For simplicity, the following description refers to stacks that include one test sample portion and one layer portion. However, one having ordinary skills in the art would understand that this description would apply to other examples, where a stack includes multiple layer portions (e.g., positioned on the top of each other) or no layer portions at all (i.e., a test sample portion by itself).

After etching, each stack is positioned above a corresponding base structure and it fully covers this base structure. That means that the stack extends outside the contact surface area of the base structure as will now be explained with reference to FIG. 10D. Specifically, FIG. 10D illustrates a test assembly 1030 that includes stacks 1031a and 1031b. In this example, each stack is formed by a portion of the corresponding test sample and a portion of the layer (that are illustrated in FIG. 10C and described above with reference to this figure). Specifically, stack 1031a is formed by test sample portion 1032a and layer portion 1034a, while stack 1031b is formed by test sample portion 1032b and layer portion 1034b.

In the same etching operation, test sample portion 1032a is formed from test sample 1012a, test sample portion 1032b—from test sample 1012b, and layer portions 1034a and 1034b—from layer 1022. Other configurations of layer portions are also within the scope of the present invention. As noted above, some characteristics, such as composition, of test samples 1012a and 1012b may be different. The etching conditions used during operation 908 are specifically selected to ensure that layer 1022 and all test samples 1012a and 1012b are sufficiently etched at the same time. For example, universal etching conditions may be used for all site isolated regions despite material and/or other differences. These etching conditions should be adequate for etching all test samples and layers provided on the substrate. As such, the etching conditions used during operation 908 are not optimized and could not be optimized to all possible variations. Instead, operation 908 may be performed using relatively aggressive etching conditions. For example, the following combinations of materials may be etched using the same etching conditions: TiN/HfOx/TiN/HfOx, TiN/TaSiN/HfOx, and TiN/AlOx/HfOx.

Despite this universal (often aggressive) etching, the interface between base structures 1008a and 1008b and corresponding test sample portions 1032a and 1032b are not impacted. These interfaces are protected by portions 1032a and 1032b being larger in size in plane of the substrate (i.e., the X-Y plane) than base structures 1008a and 1008b and fully covering these base structures 1008a and 1008b. In other words, base structures 1008a and 1008b do not extend past boundaries defined by portions 1032a and 1032b with the plane of the substrate. More specifically, edges of base structures 1008a and 1008b and corresponding portions 1032a and 1032b may be separated by at least about 5 micrometers or, more specifically, at least about 10 micrometers, for example about 20 micrometers. In some embodiments, dimension 1036 of base structures 1008a and 1008b is at least four times smaller than dimension 1038 of portions 1032a and 1032b or, more specifically, at least ten times smaller, for example, at least one hundred times smaller. For example, dimension 1036 of base structures 1008a and 1008b may be less than 600 nanometers. Specific size of structures 1008a and 1008b are described above with reference to FIG. 8E. In some embodiments, dimension 1038 of portions 1032a, 1032b, 1034a, and 1034b in the X-Y plane may be at least 50 micrometers. In some embodiments, base structures 1008a and 1008b may be concentric to corresponding portions 1032a and 1032b, i.e., base structure 1008a may be concentric to portion 1032a, while base structure 1008b may be concentric to portion 1032b.

Returning to FIG. 9, method 900 may proceed with performing measurements during operation 910. Probes may be connected to contact surfaces of the connector structure and top surface of the stack formed over the base structure. Testing may involve measuring resistance, changes in resistance, threshold voltages, and the like. Such tests may be performed on multiple test vehicles on the same substrate. The variation in these test vehicles from one site isolated region to another and within site isolated regions allow high testing throughput.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

1. A method comprising:
providing a substrate comprising a plurality of site isolated regions,
each site isolated region comprises at least one base structure comprising a conductive material,
wherein each base structure is connected to a separate connector structure for connecting to an electrical lead of a test probe;
forming test samples over the base structures in each of the site isolated regions,
the test samples formed in a combinatorial manner such that each site isolated region receives one test sample having a different characteristic than at least one test sample of another site isolated region,
the test samples comprising dielectric materials,
each test sample forming an interface layer with one of the base structures; and
etching the test samples in the same operation while each test sample protects the interface formed with the one of the base structures during etching,
wherein etching forms test sample portions from the test samples,
each test sample portion fully covering a base structure provided under this test sample portion.

2. The method of claim 1, wherein each test sample portion has a dimension, in a plane of the substrate, that is at least four times greater than a corresponding dimension of the base structure provided under this test sample portion.

3. The method of claim 1, wherein each test sample portion is concentric to the base structure provided under the test sample portion.

4. The method of claim 1, wherein each test sample portion has a dimension, in a plane of the substrate, that is at least 1 micrometer.

5. The method of claim 4, wherein each base structure has a dimension, in a plane of the substrate, that is less than 600 nanometers.

6. The method of claim 1, wherein edges of each test sample portion and edges of the base structure provided under this test sample portion are separated by at least about 20 micrometers.

7. The method of claim 1, wherein the base structures of the plurality of site isolated regions are formed from the same layer.

8. The method of claim 1, wherein at least one base structure of one site isolated region has a different composition than at least one base structure of another site isolated region.

9. The method of claim 1, wherein the substrate is cleaved into a plurality of dies prior to etching the test samples.

10. The method of claim 1, further comprising forming one or more layers over the test samples, wherein the one or more layers and the test samples are etched in the same operation, and wherein each layer portion formed during etching coincides with a test sample portion provided under this layer portion.

11. The method of claim 10, wherein each layer portion formed during etching forms a contact surface for making an electrical connection with a probe.

12. The method of claim 10, wherein the base structures are operable as first electrodes of resistive switching memory cells.

13. The method of claim 12, wherein the test sample portions are operable as resistive switching layers of the resistive switching memory cell.

14. The method of claim 13, wherein the layer portions are operable as second electrodes of the resistive switching memory cells.

15. The method of claim 1, wherein the substrate comprises connector structures and wherein each base structure is electrically connected to a separate connector structure.

16. The method of claim 15, wherein one or more of the connector structures are covered with one of the test samples prior to etching and are not covered by that test sample after etching.

17. The method of claim 1, wherein the test samples are formed using one of a High Productivity Combinatorial Atomic Layer Deposition (HPC-ALD) technique or a High Productivity Combinatorial Physical Vapor Deposition (HPC-PVD) technique.

18. The method of claim 1, wherein etching the test samples is performed using the same process conditions.

19. A method comprising:
providing a substrate comprising a first site isolated region and a second site isolated region,
the first site isolated region comprising a first base structure, the second site isolated region comprising a second base structure,
wherein the first base structure and the second base structure have the same composition and thickness,
wherein the first base structure and the second base structure are formed from a conductive material;
wherein the first base structure is connected to a first connector structure for connecting to an electrical lead of a test probe;
wherein the second base structure is connected to a second connector structure for connecting to an electrical lead of a test probe;
forming a first test sample over the first base structure and forming a second test sample over the second base structure,
the first test sample and the second test sample have different compositions,
the first test sample and the second test sample formed from different dielectric materials,
wherein the first base structure and the first test sample form a first interface and wherein the second base structure and the second test sample form a second interface,
forming a layer over the first test sample and the second test sample; and
etching the first test sample, the second test sample, and the layer in the same operation while the first test sample protects the first interface and the second test sample protects the second interface during etching,
wherein etching forms a first stack comprising a portion of the first test sample and a first portion of the layer,
wherein etching also forms a second stack comprising a portion of the second test sample and a second portion of the layer,
wherein the first stack fully covers the first base structure forming a first resistive random access memory cell and the second stack fully covers the second base structure forming a second resistive random access memory cell.

20. The method of claim 19, wherein etching the first test sample, the second test sample, and the layer is performed using the same process conditions.
